(19) United States
(12) Patent Application Publication
(10) Pub. No.: US 2008/0166837 A1
(43) Pub. Date: Jul. 10, 2008

(54) Power MOSFET wafer level chip-scale package

(76) Inventors: Tao Feng, Santa Clara, CA (US); Ming Sun, Sunnyvale, CA (US)

Correspondence Address: SCHEIN & CAI LLP, 100 CENTURY CENTER COURT, SUITE 315, SAN JOSE, CA, 95112, US

(21) Appl. No.: 11/652,385

(22) Filed: Jan. 10, 2007

(51) Int. Cl. H01L 21/44; H01L 21/00

(52) U.S. Cl. 438/113; 438/612; 257/E21.476; 257/E21.477

(57) ABSTRACT

A power MOSFET wafer level chip-scale packaging method is disclosed. The method includes the steps of electroless plating a wafer backside and a plurality of contact pads on a wafer front side and forming solder balls on the plated plurality of contact pads before dicing the wafer into a plurality of power MOSFET dies. In an alternative embodiment, the method includes the steps of providing a permanent protective layer on a wafer backside, electroless plating a plurality of contact pads on a wafer front side, and forming solder balls on the plated plurality of contact pads before dicing the wafer into a plurality of power MOSFET dies.

### BACKGROUND OF THE INVENTION

1. Field of the Invention

The present invention relates to packaging of power electronic devices and more particularly to a power MOSFET wafer level chip-scale package and related packaging processes.

2. Description of Related Art

Wafer level chip-scale packaging yields a semiconductor package having dimensions similar to or slightly larger than a semiconductor die. Generally, the semiconductor packages are formed on a wafer having a plurality of semiconductor dies and then diced from the wafer into individual packages.

In the case of power MOSFETs, the source and gate contact areas are usually on the front side of the chip while the drain is on a metalized backside of the chip. In power MOSFET wafer level chip-scale packages, the drain must be extended to the front side of the chip or a common drain structure including two dies may be used, so that solder balls for electrical connection to a printed circuit board can be formed on metal pads on the same front side of a chip. However, in each case, the metalized backside is still necessary and/or beneficial.

Particular challenges are presented in the fabrication of power MOSFET wafer level chip-scale packages. More particularly, electroless plating is conventionally utilized in under bump metallization (UBM) processes, as it does not require a mask, is simple and cost effective. Since the back metal is usually not the same as the metal on the wafer front side, contamination of the electroless plating chemicals may occur during the plating process if the backside is not protected properly.

Conventionally, a temporary protection layer of tape or resist resistant to the plating chemicals and plating temperatures is applied to the back metal in electroless plating processes. The temporary protection layer must be removed after completion of the plating process. The steps of applying and subsequently removing the temporary protective layer add complexity to, increase the cost of, and decrease the throughput of, the overall packaging process.

As an alternative to protecting the backside of a wafer, the back grinding and back metallization steps may be performed after the electroless plating step. However, this process flow may not always be available and/or convenient.

There exists then a need for a power MOSFET wafer level chip-scale packaging process that overcomes the limitations of the prior art. Preferably the process utilizes electroless plating for under bump metallization and provides a power MOSFET wafer level chip-scale package that is easy to fabricate in a cost effective and efficient manner.

### SUMMARY OF THE INVENTION

In accordance with one aspect of the invention, a power MOSFET wafer-level chip scale packaging method includes the steps of electroless plating a wafer backside and a plurality of contact pads on a wafer front side and dropping solder balls onto the plated plurality of contact pads before dicing the wafer into a plurality of power MOSFET die.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended herein.

In this respect, before explaining at least one embodiment of the invention in detail, it is to be understood that the invention is not limited in its application to the details of functional components and to the arrangements of these components set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a flowchart illustrating an exemplary method of manufacturing a power MOSFET wafer level chip-scale package in accordance with the invention;

FIG. 2 is an illustration of a step of the method illustrated in FIG. 1;

FIG. 3 is an illustration of another step of the method illustrated in FIG. 1;

FIG. 4 is an illustration of another step of the method illustrated in FIG. 1;

FIG. 5 is a flowchart illustrating another exemplary method of manufacturing a power MOSFET wafer level chip-scale package in accordance with the invention;

FIG. 6 is an illustration of a step of the method illustrated in FIG. 5;

FIG. 7 is an illustration of another step of the method illustrated in FIG. 5;

FIG. 8 is an illustration of another step of the method illustrated in FIG. 5;

FIG. 9 is an illustration of another step of the method illustrated in FIG. 5;

FIG. 10 is a flowchart illustrating yet another exemplary method of manufacturing a power MOSFET wafer level chip-scale package in accordance with the invention;

FIG. 11 is an illustration of a step of the method illustrated in FIG. 10;

FIG. 12 is an illustration of another step of the method illustrated in FIG. 10;

FIG. 13 is an illustration of another step of the method illustrated in FIG. 10;

FIG. 14 is an illustration of another step of the method illustrated in FIG. 10; and

FIG. 15 is a schematic representation of a common drain power MOSFET package in accordance with the invention.

### DETAILED DESCRIPTION OF A PREFERRED EMBODIMENT OF THE INVENTION

The present invention will now be described in detail with reference to the drawings, which are provided as illustrative examples of the invention so as to enable those skilled in the art to practice the invention. Notably, the figures and examples below are not meant to limit the scope of the present invention. Where certain elements of the present invention can be partially or fully implemented using known components, only those portions of such known components that are necessary for an understanding of the present invention will be described, and detailed descriptions of other portions of such known components will be omitted so as not to obscure the invention. Further, the present invention encompasses present and future known equivalents to the components referred to herein by way of illustration.

The present invention finds particular applicability in the wafer-level chip scale packaging of common drain power MOSFET die structures with two or more MOSFETs with drains electrically connected, or single power MOSFET die structures having a gate pad, a source pad and a drain pad on a die front side such as a lateral MOSFET, or a vertical MOSFET with a back side electrode electrically connected to a front side pad through a heavily doped sinker or other type of electrical connection. In all of these cases, a back metal is still needed but it is floating and no electrical contact needs to be made to the back metal.

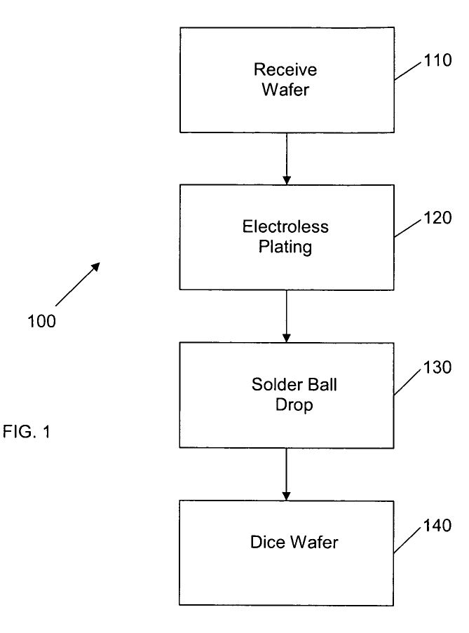

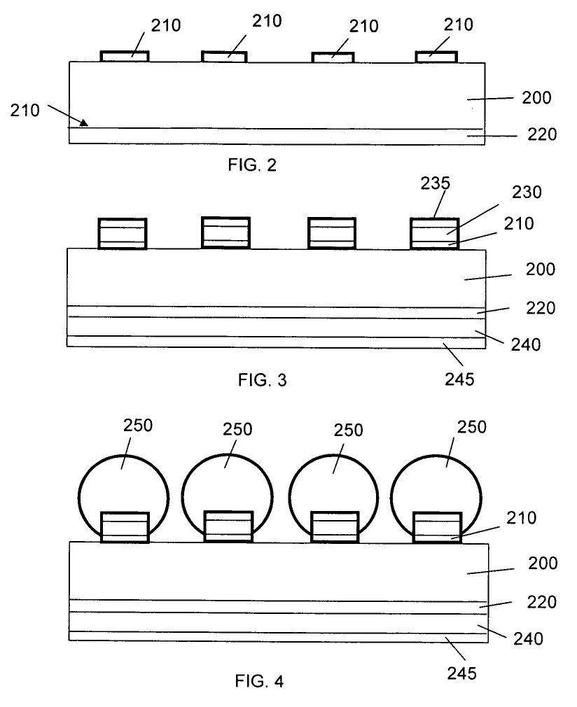

With reference to FIGS. 1-4, an exemplary power MOSFET wafer level chip-scale packaging method generally designated 100 will now be discussed. In a step 110, a wafer 200 having formed thereon a plurality of power MOSFET die is received. Wafer 200 includes a plurality of contact pads 210 that provide connectivity to the die contacts. A backside 215 of the wafer 200 includes a layer 220 of material, which may include Al or Zn that can be electrolessly plated without contaminating the plating tank. Preferably the layer 220 is formed of Ti/Al or Ti/Al alloy.

Electroless Ni plating followed by Au immersion is next performed in a step 120 to plate the plurality of contact pads 210 and the metalized backside 215. As shown in FIG. 3, a layer 230 of Ni is plated onto the contact pads 210 and a layer 240 of Ni is plated onto the metalized backside 215. A layer 235 of Au is deposited onto the layer 230 of Ni and a layer 245 of Au is plated onto the layer 240 of Ni.

In a step 130, solder balls 250 are formed on the plated contact pads 210 and in a step 140 the wafer is diced. The resulting power MOSFET wafer level chip-scale packages provide protection and good solder-ability to the die backside. The resulting backside also facilitates laser marking.

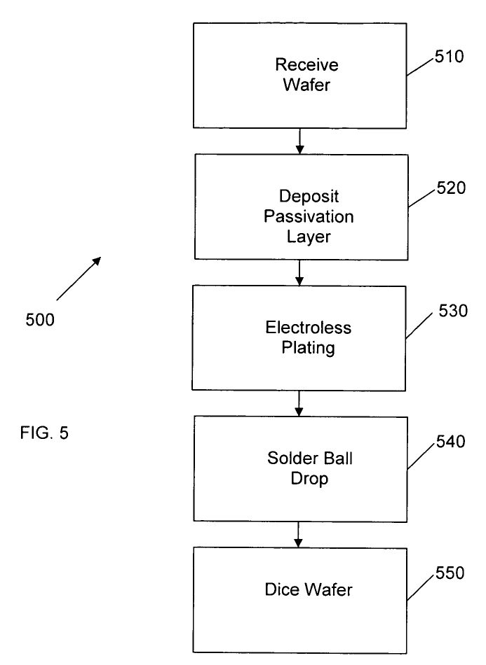

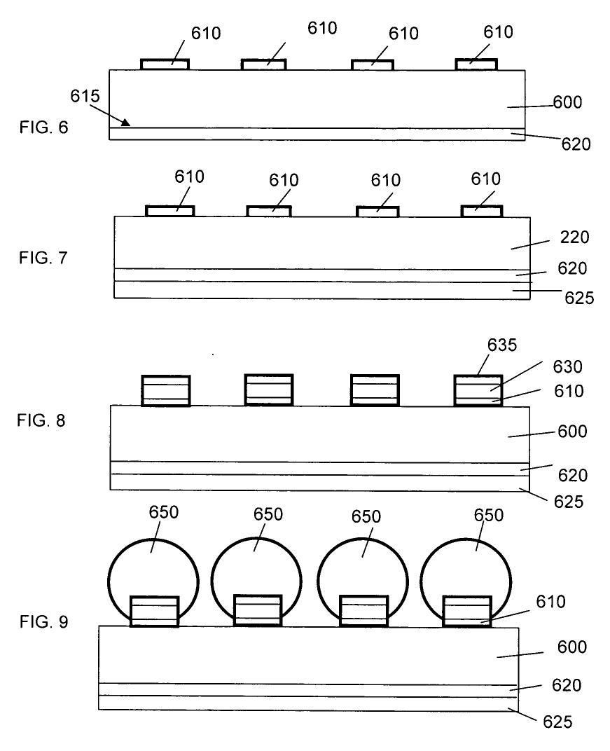

In another aspect of the invention, a power MOSFET wafer level chip-scale packaging method generally designated 500 will now be discussed with reference to FIGS. 5-9. A wafer 600 having formed thereon a plurality of power MOSFET die is received in a step 510. Wafer 600 includes a plurality of contact pads 610 that provide connectivity to the die contacts. The contact pads 610 are preferably Al or Al alloy. A backside 615 of the wafer 600 typically includes Ti/Ni/Ag layers 620.

A permanent passivation layer 625 is deposited onto the Ti/Ni/Ag layers 620 in a step 520. The permanent passivation layer 625 may be deposited by spin coating, PVD, CVD, etc. In another aspect of the invention, a high temperature tape may be used in place of the permanent passivation layer 625. The permanent passivation layer and tape material may include glass, silicon nitride, PTFE, and polyamide.

Electroless Ni plating followed by Au immersion is next performed in a step 530 to plate the plurality of contact pads 610. As shown in FIG. 7, a layer 630 of Ni is plated onto the contact pads 610. A layer 635 of Au is deposited onto the layer 630. The permanent passivation layer 625 protects the metalized backside 615 during the electroless Ni plating and prevents back metal such as Ag from contaminating the plating chemicals.

In a step 540, solder balls 650 are formed on the plated contact pads 610 and in a step 550 the wafer is diced. The wafer level chip-scale packaging method 500 provides protection to the wafer backside and easier laser marking.

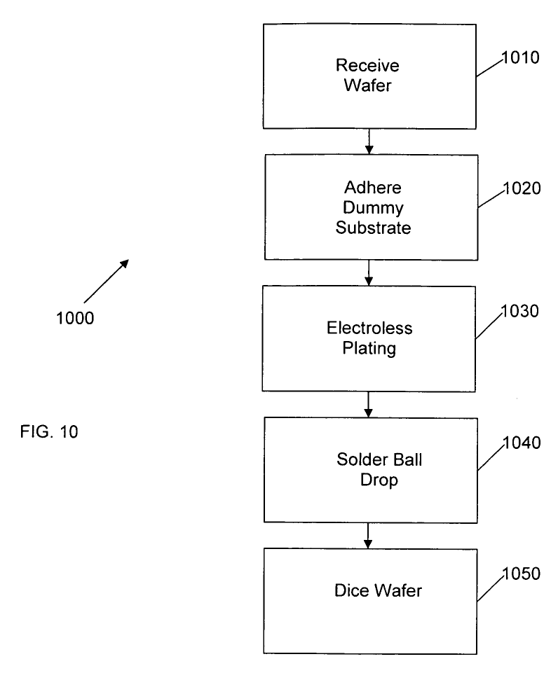

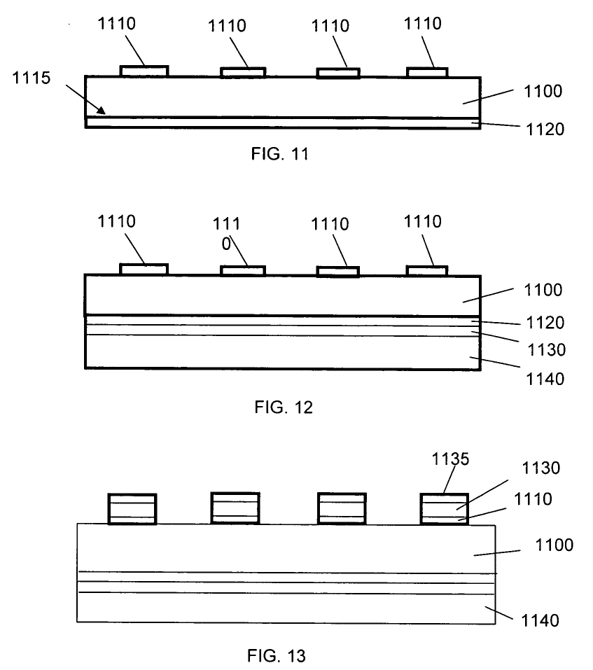

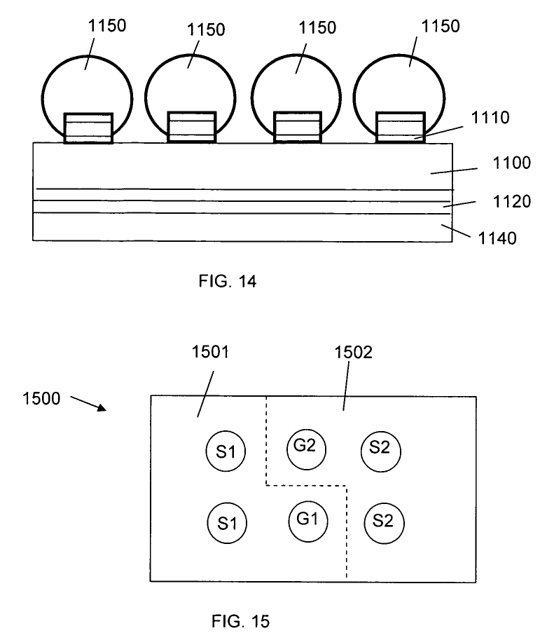

In another aspect of the invention, a power MOSFET wafer level chip-scale packaging method generally designated 1000 will now be discussed with reference to FIGS. 10-14. A wafer 1100 having formed thereon a plurality of power MOSFET die is received in a step 1010. Wafer 1100 includes a plurality of contact pads 1110 that provide connectivity to the die contacts. The contact pads 1110 are preferably Al or Al alloy. A backside 1115 of the wafer 600 typically includes Ti/Ni/Ag layers 1120.

A permanent dummy substrate 1140 is attached to the Ti/Ni/Ag layers 1120 using a thermally conductive adhesive or epoxy layer 1130 in a step 1020. The permanent dummy substrate 1140 provides protection to the wafer backside as well as enhanced mechanical strength.

Electroless Ni plating followed by Au immersion is next performed in a step 1030 to plate the plurality of contact pads 1110. As shown in FIG. 13, a layer 1130 of Ni is plated onto the contact pads 1110. A layer 1135 of Au is deposited onto the layer 1130. The permanent dummy substrate 1140 protects the metalized backside 1115 during the electroless Ni plating and prevents the Ti/Ni/Ag from contaminating the plating tank.

In alternative embodiments, a permanent dummy substrate such as permanent dummy substrate 1140 may be used to provide a protective layer as well as a support layer in an UBM process.

In a step 1040, solder balls 1150 are formed on the plated contact pads 1110 and in a step 1050 the wafer is diced.

Although the power MOSFET wafer level chip-scale packaging method 1000 has been described to include the electroless plating step 1030, other UBM processes may be utilized to plate the contact pads 1110. For example Ni—V/Cu formed with process including sputtering followed by electrolytic plating may be substituted for the electroless Ni plating step 1030.

The power MOSFET wafer level chip-scale packaging methods of the present invention provide a power MOSFET wafer level chip-scale package that is easy to fabricate in a cost effective and efficient manner. FIG. 15 shows a front side view of a resulting wafer-level chip scale package according to the claimed process after dicing of a common drain power MOSFET 1500. A common drain power MOSFET 1500 comprises two MOSFETs 1501 and 1502 formed side by side on a same die with drains electrically connected through a substrate 1510 and a back metal layer 1520. MOSFET 1501 has two source pads S1 and one gate pad G1 each connected with a solder ball. MOSFET 1502 has two source pads S2 and one gate pad G2 each connected with a solder ball. In this exemplary layout the solder balls are about 370 um in diameter and the space between the pads are about 650 um while the whole die size is about 1500×2500 um.

It is apparent that the above embodiments may be altered in many ways without departing from the scope of the invention. Further, various aspects of a particular embodiment may contain patentably subject matter without regard to other aspects of the same embodiment. Still further, various aspects of different embodiments can be combined together. Accordingly, the scope of the invention should be determined by the following claims and their legal equivalents.

What is claimed is:

1. A method of manufacturing a power MOSFET wafer level chip-scale package comprising the steps of:
electroless Ni plating a wafer backside and a plurality of contact pads on a wafer front side; and
forming solder balls on the plated plurality of contact pads.

2. The method of claim 1, further comprising the step of dicing the wafer to form a plurality of power MOSFET dies.

3. The method of claim 1, wherein the contact pads comprise Al.

4. The method of claim 1, wherein the contact pads comprise Al alloy.

5. The method of claim 1, wherein the backside comprises Ti/Al.

6. The method of claim 1, wherein the backside comprises Ti/Al alloy.

7. The method of claim 1, wherein the backside comprises a metal selected from the group consisting of Ti/Zn, Ti/Pd, or any other metal that serves as a seed layer for electroless Nickel plating.

8. The method of claim 1, wherein the power MOSFET comprises common drain power MOSFET dies.

9. The method of claim 1, wherein the plurality of contact pads comprise source, gate and drain contact pads.

10. A method of manufacturing a power MOSFET wafer level chip-scale package comprising the steps of:
providing a permanent protective layer on a wafer backside;
electroless Ni plating a plurality of contact pads on a wafer front side; and
forming solder balls on the plated plurality of contact pads.

11. The method of claim 10, wherein the protective layer comprises a passivation layer.

12. The method of claim 10, wherein the protective layer comprises a tape that can survive in electroless plating chemicals and at temperatures associated with electroless plating and solder reflow.

13. The method of claim 10, wherein the protective layer comprises a dummy substrate.

14. The method of claim 13, wherein the dummy substrate is adhered to the backside by means of an adhesive layer.

15. The method of claim 13, wherein the dummy substrate is adhered to the backside by means of an epoxy layer.

16. The method of claim 10, further comprising the step of dicing the wafer to form a plurality of power MOSFET chip-scale packages.

17. The method of claim 10, wherein the contact pads comprise Al.

18. The method of claim 10, wherein the contact pads comprise Al alloy.

19. A method of manufacturing a power MOSFET wafer level chip-scale package comprising the steps of:
providing a permanent dummy substrate on a wafer backside;
under bump metallizing a plurality of contact pads on a wafer front side through sputtering and electrolytic plating; and
forming solder balls on the plated plurality of contact pads.
